(19) United States
(12) Patent Application Publication
(10) Pub. No.: US 2023/0213394 A1
(43) Pub. Date: Jul. 6, 2023

(54) VERTICAL LIGHT-EMITTING DIODE CHIP STRUCTURE CAPABLE OF MEASURING TEMPERATURE AND TEMPERATURE MEASUREMENT CALIBRATION METHOD THEREOF

(71) Applicant: EXCELLENCE OPTO. INC., MIAOLI COUNTY (TW)

(72) Inventors: Fu-Bang CHEN, MIAOLI COUNTY (TW); Yung-Hsiang CHAO, MIAOLI COUNTY (TW); Kuo-Hsin HUANG, MIAOLI COUNTY (TW)

(21) Appl. No.: 17/568,080

(22) Filed: Jan. 4, 2022

(51) Int. Cl. G01K 15/00; H01L 33/62; H01L 33/38; G01K 7/18

(52) U.S. Cl. CPC G01K 15/005; H01L 33/62; H01L 33/38; G01K 7/186; H01L 25/0753

(57) ABSTRACT

The invention relates to a vertical light-emitting diode chip structure capable of measuring temperature and a temperature measurement calibration method thereof. A semiconductor epitaxial structure and a metal film resistance temperature measurement structure are separately arranged on the upper plane of a transverse high thermal conductivity extension structure. Through the high thermal conductivity characteristic of the transverse high thermal conductivity extension structure, the temperature of an active layer of the semiconductor epitaxial structure can be quickly transferred to the metal film resistance temperature measurement structure. The temperature measurement calibration method comprises: placing a plurality of connected and uncut package support plates into a constant temperature device at the same time to obtain a temperature calibration relation for different package support plates at the same time to reduce the temperature calibration cost in a batch mass production mode.

### FIELD OF THE INVENTION

The invention relates to chip structures of light-emitting diodes and particularly relates to a vertical light-emitting diode chip structure capable of measuring the temperature of an active layer in-situ and a temperature measurement calibration method thereof.

### BACKGROUND OF THE INVENTION

The light-emitting diode (LED) is a light source that generates high brightness by recombination of electrons and holes of semiconductors. The product is used for high-brightness sterilization (ultraviolet light), headlights and taillights (blue, yellow and red light) for vehicles, projector light sources (blue, green and red), and infrared security detection (infrared rays). In addition to high luminosity and luminous density, excellent high-power LED components also need to have good reliability. Taking a vehicle headlight module as an example, once the LED component fails, the safety at night will be affected. With the high standards of the LED for the vehicle, even the failure rate of only one of a million LED components needs to be overcome in the automobile industry. The chip light-emitting layer of the LED is the main source of heat energy and is also the highest temperature position of the component. Long-term over heat will cause the failure of a light-emitting semiconductor chip, that is, detecting the temperature of the light-emitting layer in-situ is very important for stable high-power LED components for the vehicle.

As shown in FIG. 1, a conventional vertical LED chip 1 is a surface mount device (SMD) packaged chip, a P electrode 2 is bonded to a chip-bonding conductive base 4 of a package support plate 3 through chip-bonding conductive metal 4A, and an N electrode 5 electrically connects a gold wire 6 to a wire bonding terminal 7 through wire bonding. The chip-bonding conductive base 4 and the wire bonding terminal 7 are electrically connected to an anode 9A and a cathode 9B respectively on the other side of the package support plate 3 through conductive metals 8. The chip-bonding conductive base 4 and the wire bonding terminal 7 are packaged through packaging material 3A.

The main structure of the conventional vertical LED chip 1 includes three parts: a semiconductor epitaxial structure 1A, an interface structure 1B, and a chip conductive base structure 1C from top to bottom.

The semiconductor epitaxial structure 1A is composed of an N-type semiconductor, an active layer (light-emitting layer), and a P-type semiconductor in order from top to bottom. The chip conductive base structure 1C is composed of a structural metal layer, a substitute substrate bonding layer, and a high thermal conductivity substitute substrate in order from top to bottom. The interface structure 1B is generally a structural metal layer with partial or full metal that connects the P-type semiconductor of the semiconductor epitaxial structure 1A and the chip conductive base structure 1C in ohmic contact. The P electrode 2 is located below the high thermal conductivity substitute substrate. Specifically, the active layer provides a combination of electrons and holes, and electrical energy is converted into light energy and heat energy. This area is also the main source of heat for LED components. If the temperature of the active layer is too high, the LED component will fail. Two measurement methods are used to measure the temperature: a thermal transient testing method and an infrared thermography method. The two measurement methods are used in product design and inspection to evaluate the design of the chip and inspect the product quality. The two measurement methods are indirect, and the measured temperature easily changes with the environment and the chip structure.

In addition, temperature measurement components are installed on an LED circuit module (a printed circuit board, a PCB board) to measure the in-situ temperature of the package (i.e., the vertical LED chip 1), but in the two measurement methods, the active layer is too far away from the semiconductor epitaxial structure 1A, and there are too many boundaries in between, so that the temperature of the active layer cannot be accurately measured.

In conventional technique, there is no mass-produced LED chip product that directly measures the temperature close to the position of the active layer. The reason is that the technique of placing a temperature sensor on the structure of the active layer is complicated, reduces the light-emitting area of the chip and reduces the light-emitting brightness. For small and medium-sized LED chip products in the current market, since most of the operations are conducted at lower current density, the active layer generates less heat, so there is no direct demand for temperature measurement of the active layer.

However, high-power LEDs for the headlights and projection are large-size LED components and operated at high current density. If the thermal state of the active layer can be monitored in-situ, not only the optimization design of the component is facilitated, but also the LED chip with abnormally high temperature under the operation can be detected in-situ, so as to take corresponding measures early to avoid sudden failure of the active layer due to overheat and effectively improve the use reliability of the product.

### SUMMARY OF THE INVENTION

The main purpose of the invention is to provide a vertical light-emitting diode chip structure capable of measuring temperature of an active layer in-situ, so as to meet the requirements of in-situ monitoring the thermal state of components.

The secondary purpose of the invention is to provide a temperature measurement calibration method to reduce the cost thereof.

The invention relates to a vertical light-emitting diode chip structure capable of measuring temperature, comprising a P-type electrode, a chip conductive base structure, a transverse high thermal conductivity extension structure, a metal film resistance temperature measurement structure, a semiconductor epitaxial structure and an N-type electrode. The P-type electrode is arranged on one side of the chip conductive base structure. The transverse high thermal conductivity extension structure is arranged on one side of the chip conductive base structure opposite to the P-type electrode. The metal film resistance temperature measurement structure comprises an insulating support and a temperature measurement metal film stacked in sequence. The semiconductor epitaxial structure comprises a P-type semiconductor, an active layer, and an N-type semiconductor stacked in sequence. An upper plane of the transverse high thermal conductivity extension structure is separately provided with the semiconductor epitaxial structure and the metal film resistance temperature measurement structure. The P-type semiconductor and the chip conductive base structure are in ohmic contact through the transverse high thermal conductivity extension structure. One side of the semiconductor epitaxial structure opposite to the chip conductive base structure is provided with the N-type electrode, and the N-type electrode is in ohmic contact with the N-type semiconductor.

In one embodiment, the vertical light-emitting diode chip structure comprises a package support plate. The package support plate comprises a lower plane and an upper plane. The lower plane is provided with a negative electrode, a positive electrode, a first temperature test terminal and a second temperature test terminal. The upper plane is provided with a first electrode, a second electrode, a first transfer contact and a second transfer contact. The first electrode is electrically connected to the negative electrode; the second electrode is electrically connected to the positive electrode; the first transfer contact is electrically connected to the first temperature test terminal; and the second transfer contact is electrically connected to the second temperature test terminal, wherein the N-type electrode and the first electrode are electrically connected by a wire bonding metal, and the P-type electrode is directly bonded and electrically connected to the second electrode through a chip-bonding conductive metal, and two film terminals of the temperature measurement metal film are electrically connected with the first transfer contact and the second transfer contact by a first connecting metal and a second connecting metal, respectively.

The temperature measurement calibration method comprises the following steps:

placing a plurality of package support plates which underwent the chip and electrical connection process and are connected and uncut into a constant temperature device;

making the temperature of the constant temperature device reach at least two specified temperatures respectively;

measuring resistance value of the first temperature test terminal and the second temperature test terminal of the plurality of package support plates respectively at the at least two specified temperatures; and

obtaining a temperature calibration relational expression of the plurality of package support plates respectively according to measured resistance values.

Accordingly, the upper plane of the transverse high thermal conductivity extension structure is separately provided with the semiconductor epitaxial structure and the metal film resistance temperature measurement structure. The heat generated from the active layer of the semiconductor epitaxial structure is directly transferred by the transverse high thermal conductivity extension structure to the metal film resistance temperature measurement structure. The change of temperature gradient is small, so measuring the change of the resistance of the temperature measurement metal film can monitor the temperature of the active layer in-situ, which is conducive to detecting defective products and making early corresponding measures to avoid sudden failure of components due to over-temperature, thereby effectively improves the reliability of product use. The temperature measurement calibration method achieves the effect of correcting the temperature of a large number of temperature measurement LED components at the same time.

### BRIEF DESCRIPTION OF THE DRAWINGS

FIG. 1 is a cross-section diagram of a conventional light-emitting diode packaging structure.

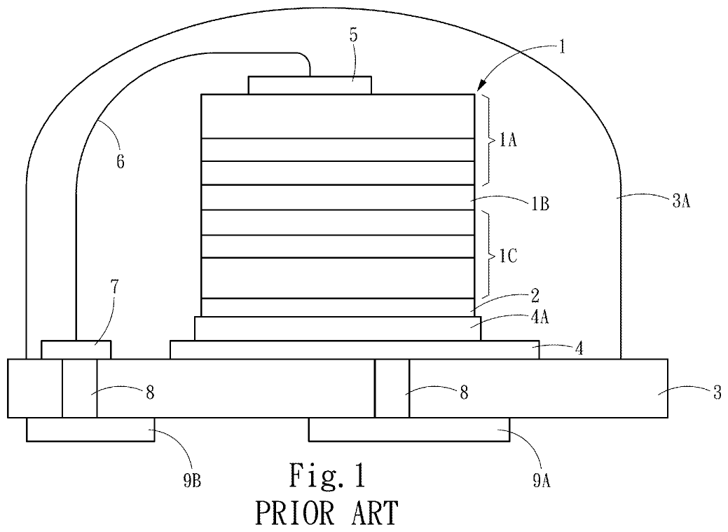

FIG. 2 is a cross-section diagram of a packaging structure of the invention.

FIG. 3A is a cross-section diagram of a resistance temperature measurement structure of a metal film of the invention.

FIG. 3B is a top view of a resistance temperature measurement structure of a metal film of the invention.

FIG. 3C is a graph of resistance versus temperature change.

FIG. 4 is a cross-section diagram of a chip structure of the invention.

FIG. 5 is a top view of a chip structure of the invention.

FIG. 6 is a schematic diagram of a temperature measurement structure arrangement of a first embodiment of the invention.

FIG. 7 is a schematic diagram of a temperature measurement structure arrangement of a second embodiment of the invention.

FIG. 8 is a schematic diagram of a temperature measurement structure arrangement of a third embodiment of the invention.

FIG. 9 is a top view of a chip structure for large-area temperature measurement of the invention.

FIG. 10 is a schematic diagram of temperature measurement calibration of the invention.

FIG. 11 is a cross-section diagram of a plurality of temperature measurement structures of the invention.

FIG. 12 is another cross-section diagram of a plurality of temperature measurement structures of the invention.

### DETAILED DESCRIPTION OF THE PREFERRED EMBODIMENTS

The detailed description and technical contents of the invention are described below with reference to the drawings.

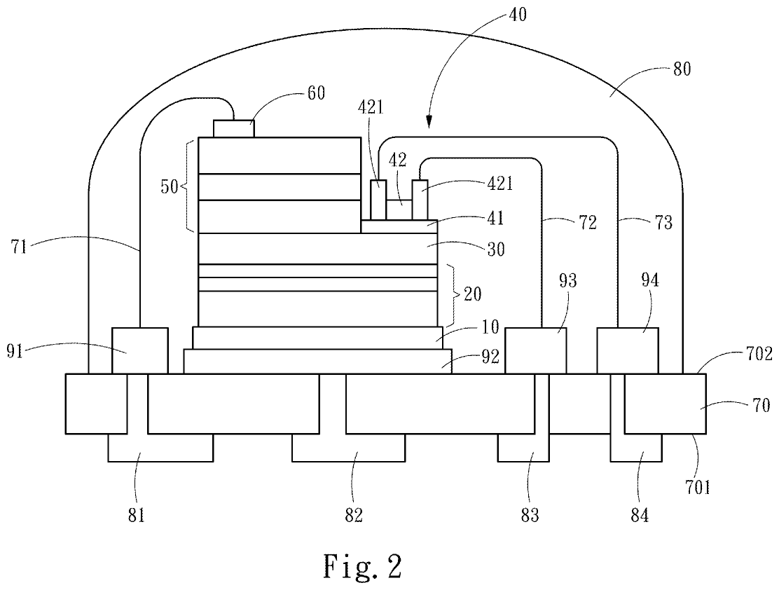

As shown in FIG. 2, the invention relates to a vertical light-emitting diode chip structure capable of measuring temperature, which comprises a P-type electrode 10, a chip conductive base structure 20, a transverse high thermal conductivity extension structure 30, a metal film resistance temperature measurement structure 40, a semiconductor epitaxial structure 50, an N-type electrode 60 and a package support plate 70. The P-type electrode 10 is arranged on one side of the chip conductive base structure 20, and the transverse high thermal conductivity extension structure 30 is arranged on one side of the chip conductive base structure 20 opposite to the P-type electrode 10.

The package support plate 70 comprises a lower plane 701 and an upper plane 702. The lower plane 701 is provided with a negative electrode 81, a positive electrode 82, a first temperature test terminal 83 and a second temperature test terminal 84. The upper plane 702 is provided with a first electrode 91 electrically connected to the negative electrode 81, a second electrode 92 electrically connected to the positive electrode 82, a first transfer contact 93 electrically connected to the first temperature test terminal 83 and a second transfer contact 94 electrically connected to the second temperature test terminal 84, wherein the N-type electrode 60 and the first electrode 91 are electrically connected by a wire bonding metal 71, and the P-type electrode 10 is directly bonded and electrically connected to the second electrode 92 through a chip-bonding conductive metal (not shown in the figure). In one embodiment, the invention further comprises a packaging material 80 that covers and encapsulates the upper plane 702 of the package support plate 70 to form a protecting structure.

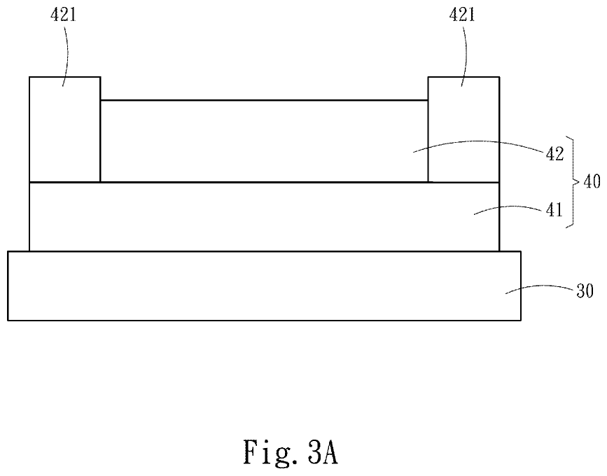

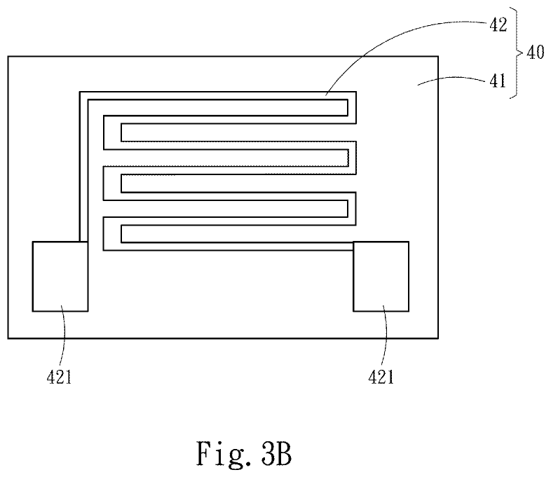

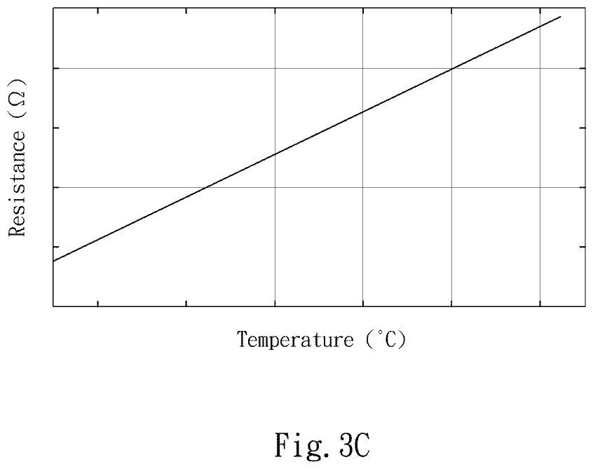

As shown in FIGS. 3A, 3B and 3C, the metal film resistance temperature measurement structure 40 comprises an insulating support 41 and a temperature measurement metal film 42 stacked in sequence. In one embodiment, the temperature measurement metal film 42 is in a shape of a long metal wire. The temperature measurement metal film 42 is repeatedly bent back and forth on the insulating support 41. The temperature measurement metal film 42 comprises two film terminals 421; and the two film terminals 421 of the temperature measurement metal film 42 are electrically connected with the first transfer contact 93 and the second transfer contact 94 by a first connecting metal 72 and a second connecting metal 73, respectively. In addition, the material of the temperature measurement metal film 42 is any one selected from platinum (Pt) or platinum alloy, and the metal film needs to have good linear temperature coefficient of the electrical resistance (TCR). The material of the insulating support 41 is any one selected from TiO₂, SiO₂, Al₂O₃ or MgO. As shown in FIG. 3C, the resistance of the temperature measurement metal film 42 is approximately proportional to temperature.

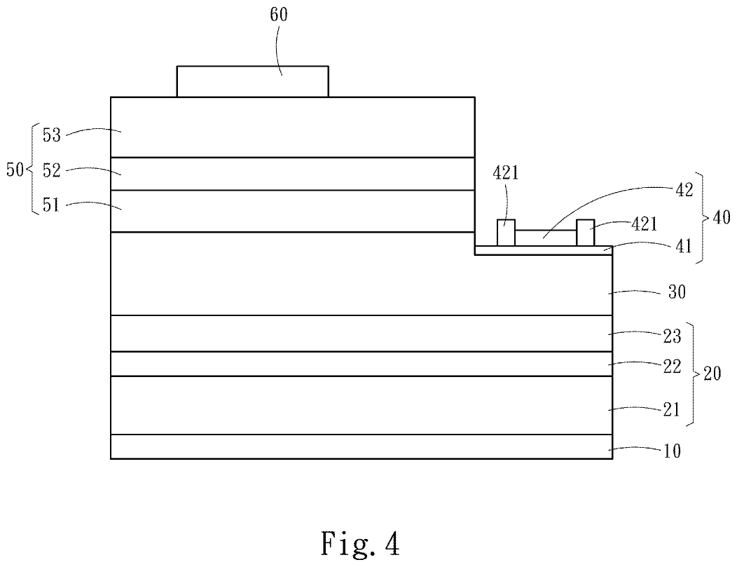

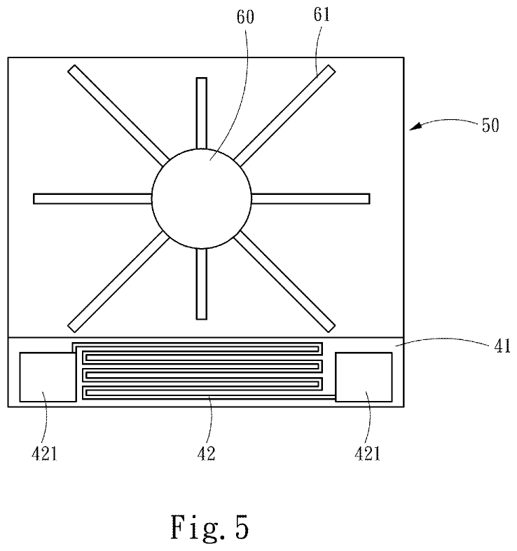

As shown in FIGS. 4 and 5, the semiconductor epitaxial structure 50 comprises a P-type semiconductor 51, an active layer 52, and an N-type semiconductor 53 stacked in sequence. An upper plane of the transverse high thermal conductivity extension structure 30 is separately provided with the semiconductor epitaxial structure 50 and the metal film resistance temperature measurement structure 40. The P-type semiconductor 51 and the chip conductive base structure 20 are in ohmic contact through the transverse high thermal conductivity extension structure 30, one side of the semiconductor epitaxial structure 50 opposite to the chip conductive base structure 20 is provided with the N-type electrode 60, and the N-type electrode 60 is in ohmic contact with the N-type semiconductor 53. In one embodiment, the chip conductive base structure 20 comprises a high thermal conductivity substitute substrate 21, a substitute substrate bonding layer 22 and a structural metal layer 23 in order from bottom to top. The N-type electrode 60 is connected to a plurality of extension electrodes 61 to improve the distribution uniformity of current.

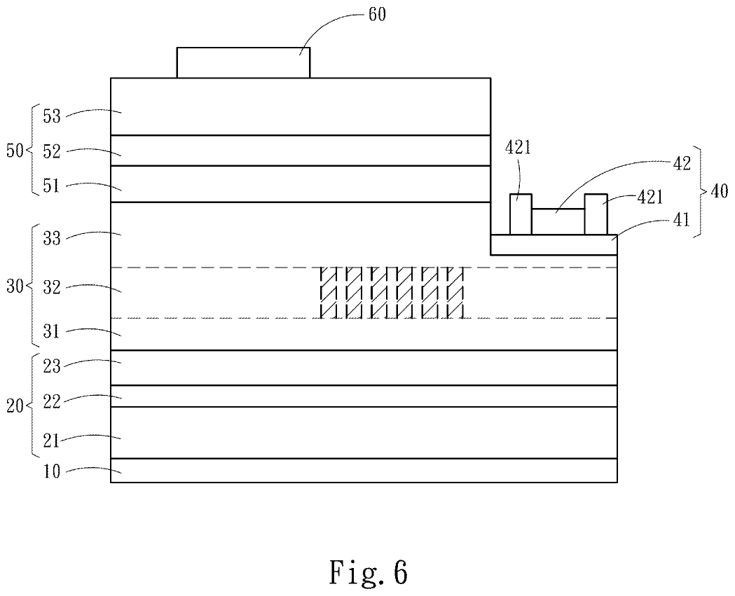

FIG. 6 shows a schematic diagram of a temperature measurement structure arrangement of a first embodiment. The transverse high thermal conductivity extension structure 30 comprises a high electric and thermal conductivity metal layer 31, an ohmic contact layer 32 and a high concentration P-type semiconductor conductive layer 33 stacked in sequence. The high electric and thermal conductivity metal layer 31 is located above the structural metal layer 23. The P-type semiconductor 51 and the metal film resistance temperature measurement structure 40 are separately located on the high concentration P-type semiconductor conductive layer 33.

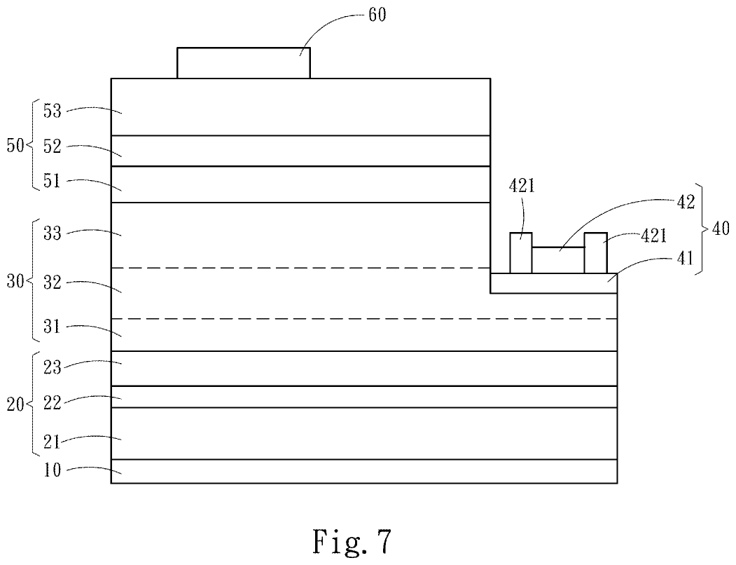

FIG. 7 shows a schematic diagram of a temperature measurement structure arrangement of a second embodiment. The high electric and thermal conductivity metal layer 31 is located above the structural metal layer 23. The P-type semiconductor 51 is located on the high concentration P-type semiconductor conductive layer 33, and the metal film resistance temperature measurement structure 40 is located on the ohmic contact layer 32.

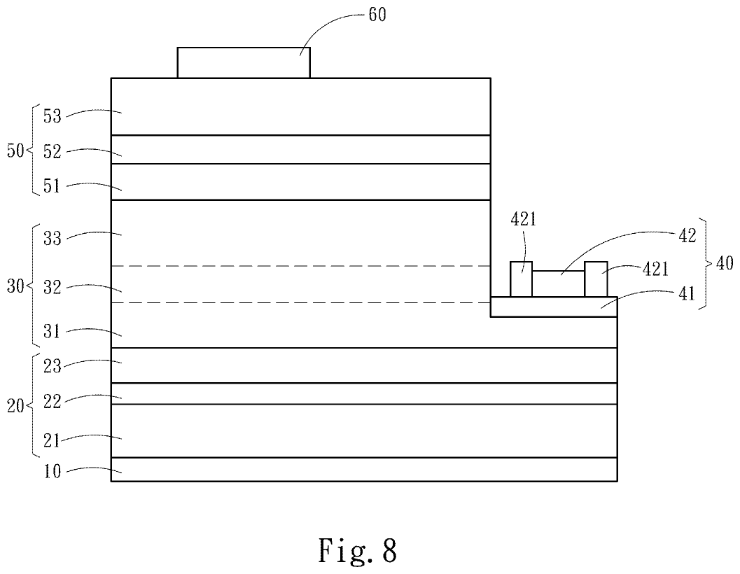

FIG. 8 shows a schematic diagram of a temperature measurement structure of a third embodiment. The high electric and thermal conductivity metal layer 31 is located above the structural metal layer 23, the P-type semiconductor 51 is located on the high concentration P-type semiconductor conductive layer 33, and the metal film resistance temperature measurement structure 40 is located on the high electric and thermal conductivity metal layer 31.

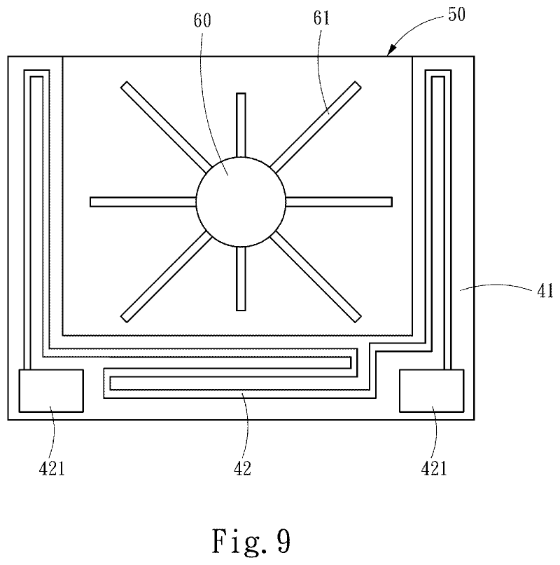

FIG. 9 shows a top view of a chip structure for large-area temperature measurement of the invention. The insulating support 41 is arranged around at least one side of the semiconductor epitaxial structure 50. For example, as shown in FIG. 5, the insulating support 41 is arranged around one side of the semiconductor epitaxial structure 50. As shown in FIG. 9, the insulating support 41 is arranged around three sides of the semiconductor epitaxial structure 50. In other embodiments, the insulating support 41 is arranged around two or four sides of the semiconductor epitaxial structure 50.

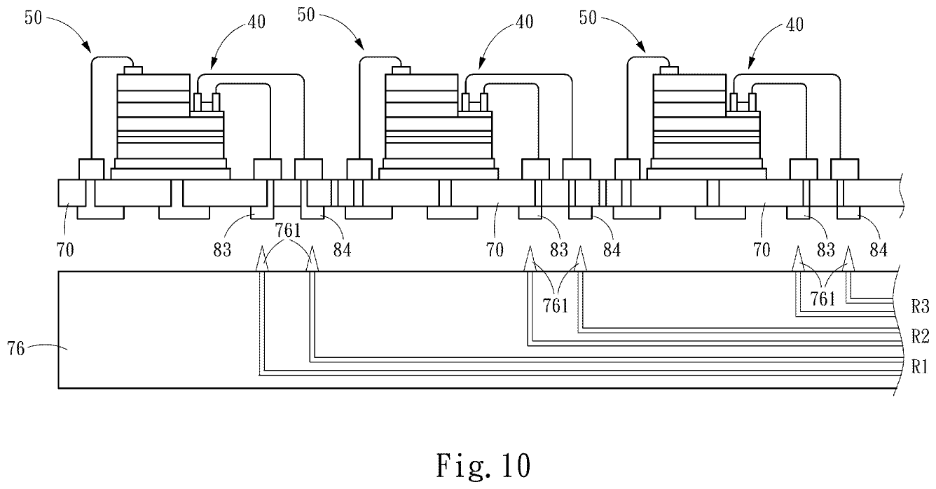

FIG. 10 shows a schematic diagram of the implementation of temperature measurement calibration of the invention. In order to improve mass production and save cost, the invention provides a batch temperature measurement calibration method of the vertical light-emitting diode chip structure, comprising the following steps:

placing a plurality of package support plates 70 which are connected and uncut into a constant temperature device (not shown);

making the temperature of the constant temperature device reach at least two specified temperatures respectively;

measuring resistance values R1, R2 and R3 between the first temperature test terminal 83 and the second temperature test terminal 84 of the plurality of package support plates 70 respectively at the at least two specified temperatures (for example, 0° C. and 150° C.); and

obtaining a temperature calibration relational expression of the plurality of package support plates 70 respectively according to the resistance values R1, R2 and R3.

When measuring the resistance values R1, R2 and R3, a probe card 76 is used. The probe card 76 comprises measuring probes 761 corresponding to the first temperature test terminal 83 and the second temperature test terminal 84 of the plurality of package support plates 70 to measure the resistance values R1, R2 and R3 between the first temperature test terminal 83 and the second temperature test terminal 84.

As described in the steps, the temperature measurement calibration of a plurality of package support plates 70 are completed simultaneously, which saves the cost.

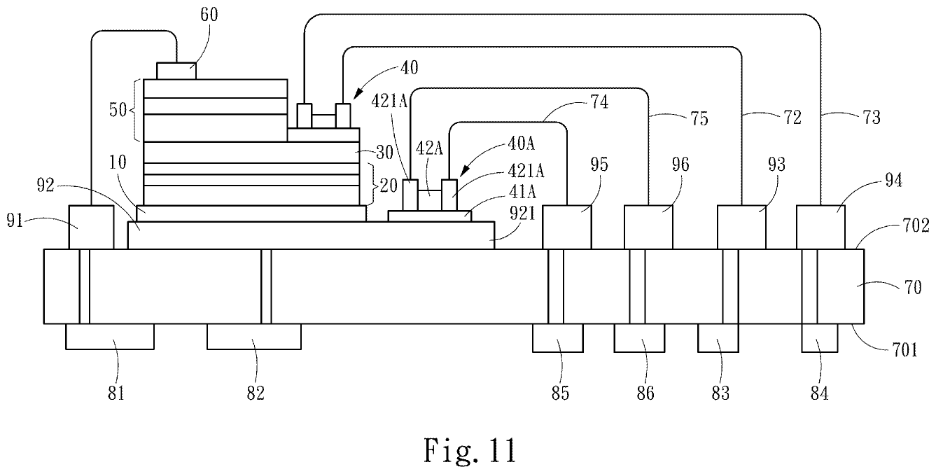

As shown in FIG. 11, it shows a cross-section diagram of a plurality of temperature measurement structures of the invention. The second electrode 92 extends laterally to form a temperature measurement area 921; the temperature measurement area 921 is provided with another metal film resistance temperature measurement structure 40A. The another metal film resistance temperature measurement structure 40A comprises another insulating support 41A and another temperature measurement metal film 42A stacked in sequence. The lower plane 701 is further provided with a third temperature test terminal 85 and a fourth temperature test terminal 86; the upper plane 702 is further provided with a third transfer contact 95 electrically connected to the third temperature test terminal 85 and a fourth transfer contact 96 electrically connected to the fourth temperature test terminal 86; and the two film terminals 421A of the another temperature measurement metal film 42A are electrically connected to the third transfer contact 95 and the fourth transfer contact 96 through a third connecting metal 74 and a fourth connecting metal 75, respectively.

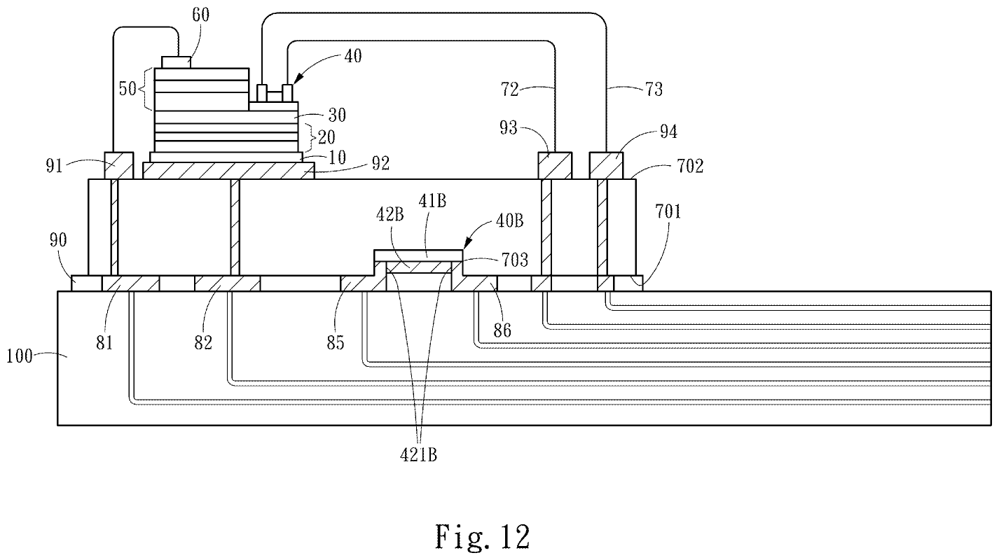

As shown in FIG. 12, it shows another cross-section diagram of a plurality of temperature measurement structures of the invention. The lower plane 701 is further provided with the third temperature test terminal 85 and the fourth temperature test terminal 86, and another metal film resistance temperature measurement structure 40B; the another metal film resistance temperature measurement structure 40B comprises another insulating support 41B and another temperature measurement metal film 42B stacked in sequence, and two film terminals 421B of the another temperature measurement metal film 42B are electrically connected with the third temperature test terminal 85 and the fourth temperature test terminal 86, respectively. In one embodiment, the lower plane 701 further comprises an accommodating groove 703 for accommodating the another metal film resistance temperature measurement structure 40B. In order to increase the heat dissipation efficiency, the package support plate 70 is further provided with an insulating and high thermal conductivity filler 90 on the lower plane 701. The package support plate 70 is fixed on a circuit board 100 via the insulating and high thermal conductivity filler 90.

The improvement of the invention comprises:

1. The metal film resistance temperature measurement structure is located to close to the semiconductor epitaxial structure, and the temperature of the chip is measured in-situ at the position close to the active layer. Abnormal high temperature of the semiconductor epitaxial structure is measured and detected, and preventive measures can reduce the current on the spot to avoid burnout or doing maintenance check before scheduled time. According to the temperature of the active layer, engineering optimization of the chip conductive base structure and the packaging material can he conducted to improve the heat dissipation capacity of the component and increase the reliability.

2. A plurality of package support plates which are connected and uncut are placed into a constant temperature device at a time, so that a batch temperature calibration relational expression of a large number of chips is measured, thereby solving the problems of high cost and complex operation of testing components individually.

3. The temperature of the semiconductor epitaxial structure close to the active layer is measured simply, directly and in-situ. If there is an abnormally high temperature, safety procedures (warning, current reduction or turn-off) can be carried out to prevent a single component from burning that affects the overall lighting.

4. A plurality of metal film resistance temperature measurement structures are arranged at different positions of the vertical light-emitting diode chip structure. Two temperature values are used to estimate the change of temperature gradient, which allows design and optimization of heat dissipation, monitoring of heat dissipation, and emergency repairing to be efficient.

What is claimed is:

1. A vertical light-emitting diode chip structure capable of measuring temperature, comprising:
a P-type electrode;
a chip conductive base structure, wherein the P-type electrode is arranged on one side of the chip conductive base structure;
a transverse high thermal conductivity extension structure, which is arranged on one side of the chip conductive base structure opposite to the P-type electrode;
a metal film resistance temperature measurement structure, which comprises an insulating support and a temperature measurement metal film stacked in sequence;
a semiconductor epitaxial structure, which comprises a P-type semiconductor, an active layer, and an N-type semiconductor stacked in sequence, wherein an upper plane of the transverse high thermal conductivity extension structure is separately provided with the semiconductor epitaxial structure and the metal film resistance temperature measurement structure, and the P-type semiconductor and the chip conductive base structure are in ohmic contact through the transverse high thermal conductivity extension structure; and
an N-type electrode, wherein one side of the semiconductor epitaxial structure opposite to the chip conductive base structure is provided with the N-type electrode, and the N-type electrode is in ohmic contact with the N-type semiconductor.

2. The vertical light-emitting diode chip structure according to claim 1, wherein the transverse high thermal conductivity extension structure comprises a high electric and thermal conductivity metal layer, an ohmic contact layer and a high concentration P-type semiconductor conductive layer stacked in sequence; and the chip conductive base structure comprises a high thermal conductivity substitute substrate, a substitute substrate bonding layer and a structural metal layer in order from bottom to top.

3. The vertical light-emitting diode chip structure according to claim 2, wherein the high electric and thermal conductivity metal layer is located above the structural metal layer, and the P-type semiconductor and the metal film resistance temperature measurement structure are separately located on the high concentration P-type semiconductor conductive layer.

4. The vertical light-emitting diode chip structure according to claim 2, wherein the high electric and thermal conductivity metal layer is located above the structural metal layer, the P-type semiconductor is located on the high concentration P-type semiconductor conductive layer, and the metal film resistance temperature measurement structure is located on the ohmic contact layer.

5. The vertical light-emitting diode chip structure according to claim 2, wherein the high electric and thermal conductivity metal layer is located above the structural metal layer, the P-type semiconductor is located on the high concentration P-type semiconductor conductive layer, and the metal film resistance temperature measurement structure is located on the high electric and thermal conductivity metal layer.

6. The vertical light-emitting diode chip structure according to claim 1, wherein the temperature measurement metal film is in a shape of a long metal wire.

7. The vertical light-emitting diode chip structure according to claim 6, wherein the temperature measurement metal film is repeatedly bent back and forth on the insulating support.

8. The vertical light-emitting diode chip structure according to claim 1, wherein the material of the temperature measurement metal film is any one selected from platinum (Pt) or platinum alloy; and the material of the insulating support is any one selected from TiO₂, SiO₂, Al₂O₃ or MgO.

9. The vertical light-emitting diode chip structure according to claim 1, wherein the insulating support is arranged around at least one side of the semiconductor epitaxial structure.

10. The vertical light-emitting diode chip structure according to claim 1, further comprising a package support plate, wherein the package support plate comprises a lower plane and an upper plane, the lower plane is provided with a negative electrode, a positive electrode, a first temperature test terminal and a second temperature test terminal, the upper plane is provided with a first electrode electrically connected to the negative electrode, a second electrode electrically connected to the positive electrode, a first transfer contact electrically connected to the first temperature test terminal and a second transfer contact electrically connected to the second temperature test terminal, wherein the N-type electrode and the first electrode are electrically connected by a wire bonding metal, and the P-type electrode is directly bonded and electrically connected to the second electrode through a chip-bonding conductive metal, and two film terminals of the temperature measurement metal film are electrically connected with the first transfer contact and the second transfer contact by a first connecting metal and a second connecting metal, respectively.

11. The vertical light-emitting diode chip structure according to claim 10, further comprising a packaging material that covers and encapsulates the upper plane of the package support plate.

12. The vertical light-emitting diode chip structure according to claim 10, wherein the second electrode extends laterally to form a temperature measurement area; the temperature measurement area is provided with another metal film resistance temperature measurement structure; the another metal film resistance temperature measurement structure comprises another insulating support and another temperature measurement metal film stacked in sequence; the lower plane is further provided with a third temperature test terminal and a fourth temperature test terminal; the upper plane is further provided with a third transfer contact electrically connected to the third temperature test terminal and a fourth transfer contact electrically connected to the fourth temperature test terminal; and the two film terminals of the another temperature measurement metal film are electrically connected to the third transfer contact and the fourth transfer contact through a third connecting metal and a fourth connecting metal, respectively.

13. The vertical light-emitting diode chip structure according to claim 10, wherein the lower plane is further provided with a third temperature test terminal, a fourth temperature test terminal, and another metal film resistance temperature measurement structure; the another metal film resistance temperature measurement structure comprises another insulating support and another temperature measurement metal film stacked in sequence, and two film terminals of the another temperature measurement metal film are electrically connected with the third temperature test terminal and the fourth temperature test terminal.

14. The vertical light-emitting diode chip structure according to claim 13, wherein the lower plane further comprises an accommodating groove for accommodating the another metal film resistance temperature measurement structure.

15. The vertical light-emitting diode chip structure according to claim 14, wherein the package support plate is provided with an insulating and high thermal conductivity filler on the lower plane, and the package support plate is fixed on a circuit board via the insulating and high thermal conductivity filler.

16. A temperature measurement calibration method of the vertical light-emitting diode chip structure of claim 10, comprising the following steps:
placing a plurality of package support plates which are connected and uncut into a constant temperature device;
making a temperature of the constant temperature device reach at least two specified temperatures respectively;
measuring resistance values between the first temperature test terminal and the second temperature test terminal of the plurality of package support plates respectively at the at least two specified temperatures; and
obtaining a temperature calibration relational expression of the plurality of package support plates respectively according to the resistance values.
